(19) United States
(12) Patent Application Publication
(10) Pub. No.: US 2023/0178688 A1
(43) Pub. Date: Jun. 8, 2023

(54) LIGHT-EMITTING DEVICE AND LIGHT-EMITTING APPARATUS

(71) Applicant: XIAMEN SANAN OPTOELECTRONICS TECHNOLOGY CO., LTD., XIAMEN (CN)

(72) Inventors: WEICHUN TSENG, XIAMEN (CN); CHUNG-YING CHANG, XIAMEN (CN); YASHU ZANG, XIAMEN (CN); BIN JIANG, XIAMEN (CN); SIHE CHEN, XIAMEN (CN); SIYI LONG, XIAMEN (CN)

(21) Appl. No.: 18/055,573

(22) Filed: Nov. 15, 2022

(30) Foreign Application Priority Data
Dec. 5, 2021 (CN) 202111481531.3

(51) Int. Cl. H01L 33/40

(52) U.S. Cl. CPC H01L 33/405; H01L 33/32

(57) ABSTRACT

A light-emitting device includes an epitaxial light-emitting structure formed on a substrate, a first electrode and a second electrode. The epitaxial light-emitting structure sequentially includes: a first type semiconductor layer including an Al component and electrically connected to the first electrode; an active layer; a second type semiconductor layer electrically connected to the second electrode; a first recess extending from the second type semiconductor layer to the first type semiconductor layer and having a projected area on the substrate ranging from 20% to 70% of that of the epitaxial light-emitting structure; and a second recess extending from the first type semiconductor layer toward the substrate. A light-emitting apparatus is also disclosed.

### CROSS-REFERENCE TO RELATED APPLICATION

This application claims priority of Chinese Patent Application No. 202111481531.3, filed on Dec. 5, 2021.

### FIELD

The disclosure relates to a semiconductor optoelectronic device, and more particularly to a light-emitting device. The disclosure also relates to a light-emitting apparatus including the light-emitting device.

### BACKGROUND

Light-emitting diode (LED) is a type of semiconductor optoelectronic device, which is commonly made by a semiconductor material such as gallium nitride, gallium arsenide, gallium phosphide, gallium arsenide phosphide, etc. The LED includes a p-n junction structure. When a forward voltage is applied to the p-n junction structure, electrons move from the n-type region toward the p-type region while holes move toward the p-type region. The electrons and the holes are combined near the p-n junction, resulting in release of energy in the form of light that is emitted by the LED. The LED is widely applied as a light source because of its advantageous characteristics, e.g., high light intensity, high luminous efficacy, small size, and long lifetime, etc. In recent years, the wide application of an ultra-violet light-emitting diode (UV-LED), particularly a deep ultra-violet light-emitting diode (DUV-LED), has attracted great attention and has become a new research focus.

The UV-LED is a type of solid state semiconductor optoelectronic device that may convert electrical energy into ultra-violet light, and is widely applied in several fields such as medical treatment, anti-counterfeiting, water purification, air purification, storage of computing data, military, etc. In recent years, with the increasing demand for drinking water, daily sterilization and disinfection, application of the DUV-LED has become a hot research topic. Thus, in order to enhance the disinfection effect of the DUV-LED, various means have been used to extract light from the DUV-LED as much as possible so as to maximize the light extraction efficiency of the DUV-LED.

Currently, the application DUV-LED encounters various technical barriers such as high operating voltage. Specifically, the DUV-LED includes an epitaxial layer that is doped with a high content of aluminum component, which makes it difficult for the n-type side of the epitaxial layer to form an ohmic contact. In addition, when the DUV-LED is driven, lateral propagation of the current in the epitaxial layer is poor due to material property thereof. Therefore, the DUV-LED has a relatively high overall operating voltage.

In order to achieve the goal of maximum luminous efficacy of the DUV-LED, it is necessary to utilize various techniques in a method for making the DUV-LED to extract light therefrom, so as to improve the luminous efficacy of the DUV-LED. For instance, stacking a reflection layer or coating a distributed Bragg reflector (DBR) on a light-emitting structure of the DUV-LED, roughening side walls and surfaces of the light-emitting structure, or using a patterned sapphire substrate (PSS) to serve as a substrate of the DUV-LED. However, these conventional techniques of improving the light extraction efficiency only allows DUV-LED with axial light emission to have great performance. When these conventional techniques are applied to the DUV-LED with lateral light emission, the light extraction efficiency is greatly reduced.

Thus, how to effectively improve the luminous efficacy of the DUV-LED with lateral light emission and reduce the operating voltage has become an important issue to be solved by those skilled in the art.

### SUMMARY

Therefore, an object of the disclosure is to provide a light-emitting device, and a light-emitting apparatus that can alleviate at least one of the drawbacks of the prior art.

According to a first aspect of the disclosure, a light-emitting device includes a substrate, an epitaxial light-emitting structure, and a first electrode, and a second electrode. The substrate has an upper surface. The epitaxial light-emitting structure is disposed on the upper surface of the substrate, and includes a first type semiconductor layer, an active layer, and a second type semiconductor layer formed on the upper surface in such order, a first recess that extends from the second type semiconductor layer to the first type semiconductor layer through the active layer, and a second recess that extends from the first type semiconductor layer toward the upper surface. The first type semiconductor layer has an inner surface that defines the second recess. The first electrode is disposed in the second recess, at least partially covers the inner surface of the first type semiconductor layer, and is electrically connected to the first type semiconductor layer. The second electrode is disposed on the second type semiconductor layer, and is electrically connected to the second type semiconductor layer. The first type semiconductor layer includes an aluminum component. In a top view of the light-emitting device, the first recess has a projected area on the upper surface ranging from 20% to 70% of that of the epitaxial light-emitting structure.

According to a second aspect of the disclosure, a light-emitting apparatus includes at least one the aforesaid light-emitting device.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a top view illustrating a first embodiment of a light-emitting device according to the disclosure.

FIG. 2 is a sectional view taken along line A-A of FIG. 1.

FIGS. 3 to 8 are schematic views illustrating consecutive steps of a method for manufacturing the first embodiment of the light-emitting device of the disclosure.

FIG. 9 is a top view illustrating a second embodiment of a light-emitting device according to the disclosure.

FIG. 10 is a top view illustrating a third embodiment of a light-emitting device according to the disclosure.

FIGS. 11 to 13 are enlarged sectional views illustrating variations in a configuration of a second recess of the light-emitting device.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

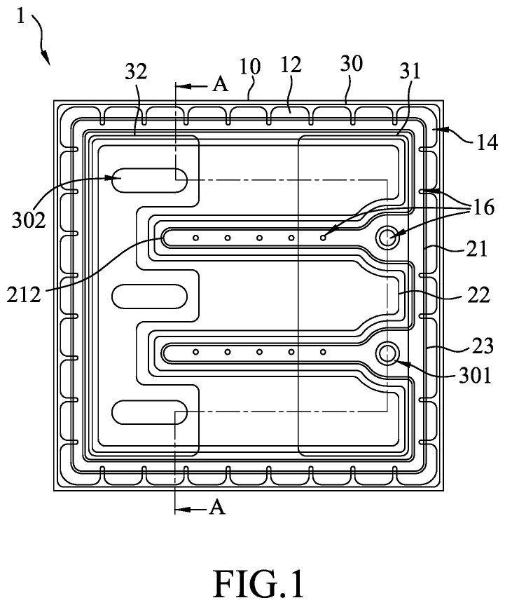

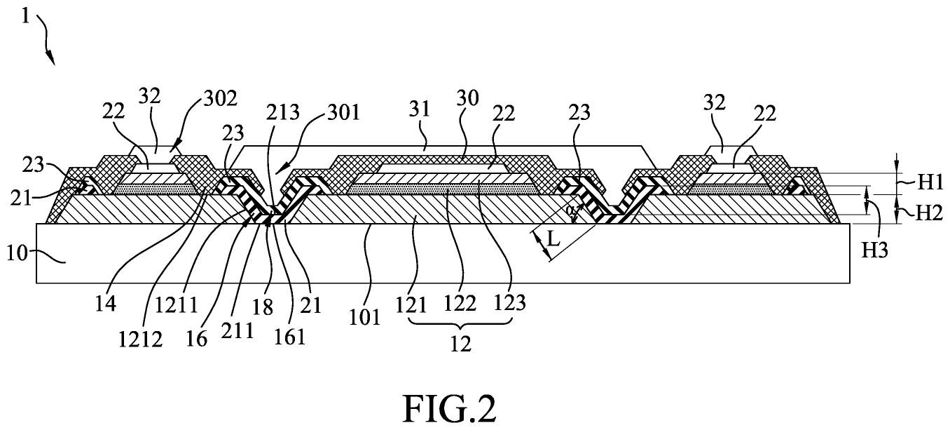

FIGS. 1 and 2 each illustrates a first embodiment of a light-emitting device according to the present disclosure. FIG. 1 is a top view illustrating the light-emitting device, and FIG. 2 is a sectional view taken along line A-A of FIG. 1. In this embodiment, an ultra-violet light-emitting device is taken as an unlimited example of the light-emitting device.

Referring to FIGS. 1 and 2, the light-emitting device 1 includes a substrate 10 having an upper surface 101, an epitaxial light-emitting structure 12 disposed on the upper surface substrate 10, a first electrode 21, and a second electrode 22.

Referring to FIG. 2, the substrate 10 may be a transparent substrate or a translucent substrate, which allows a light generated by the light-emitting structure 12 to penetrate therethrough and exit from a side thereof distal from the light-emitting structure 12. For instance, the substrate 10 may be one of a sapphire substrate, a patterned sapphire substrate, a silicon substrate, a silicon carbide substrate, a gallium nitride substrate, a glass substrate, etc., but is not limited thereto.

In some embodiments, the substrate 10 is a patterned substrate that has a single-layer textured structure or a multi-layered textured structure. Furthermore, the textured structure may include a base portion and at least one light extraction layer formed on the base portion. The light extraction layer has a refractive index less than that of the substrate 10, and a thickness greater than half of a height of the textured structure, so that light extraction efficiency of the light-emitting device 1 can be further enhanced. In certain embodiments, the textured structure includes a plurality of elliptic cylinder-shaped protrusions. The light extraction layer may be made by a material that has the refractive index less than 1.6 (e.g. silicon dioxide, etc.). In certain embodiments, the substrate 10 may be thinned or removed for making a thin-film chip.

Referring to FIG. 2, the epitaxial light-emitting structure 12 includes a first type semiconductor layer 121, an active layer 122, and a second type semiconductor layer 123 formed on the upper surface 101 in such order, and is formed with a first recess 14 and a second recess 16. The first type semiconductor layer 121 is doped with a first conductivity type dopant, and the second type semiconductor layer 123 is doped with a second conductivity type dopant that is opposite in conductivity type to the first conductivity type dopant. For instance, the first conductivity type dopant may be an n-type dopant that provides electrons, and the second conductivity type dopant may be a p-type dopant that provides holes, and vice versa.

In this embodiment, the first type semiconductor layer 121 formed on the upper surface 101 of the substrate 10 is an n-type semiconductor layer, e.g., a silicon-doped gallium nitride semiconductor layer. The first type semiconductor layer 121 includes an aluminum component such that the light-emitting device 1 emits ultra-violet light. In other embodiments, the light-emitting device 1 further includes a buffer layer formed between the substrate 10 and the first type semiconductor layer 121. In certain embodiments, the first type semiconductor layer 121 may be connected to the substrate 10 through an adhesive layer. Furthermore, the first type semiconductor layer 121 includes an inner surface 1211 defining the second recess 16 and a top surface 1212 that is connected to the inner surface 1211 and away from the upper surface 101.

In this embodiment, the active layer 122 is formed on the first type semiconductor layer 121 opposite to the substrate 10, and serves as a light-emitting layer that has a quantum well (QW) structure. In certain embodiments, the active layer 122 has a multiple quantum well (MQW) structure that has a plurality of well layers and a plurality of barrier layers which are alternately disposed on one another. It should be noted that, a wavelength of the light emitted by the active layer 122 is determined by the thickness and composition of the well layer of the active layer 122. For example, the active layer 122 may emit light that has a predetermined wavelength (e.g., ultra-violet light, blue light, green light, etc.) by adjusting the composition of the well layer. In this embodiment, the active layer 122 is configured to emit light that has a wavelength ranging from 200 nm to 420 nm.

As mentioned above, the second type semiconductor layer 123 is formed on the active layer 122 opposite to the first type semiconductor layer 121. In this embodiment, the second type semiconductor layer 123 is a p-type semiconductor layer, e.g., a magnesium-doped gallium nitride semiconductor layer. Each of the first type semiconductor layer 121 and the second type semiconductor layer 123 may be formed as a single-layer structure, but is not limited thereto. In other embodiment, each of the first and second type semiconductor layers may be a multiple-layered structure such as a super lattice structure.

The first recess 14 extends from the second type semiconductor layer 123 to the first type semiconductor layer 121 through the active layer 122 to expose a part of the top surface 1212 of the first type semiconductor layer 121. That is, the first recess 14 penetrates downwardly from a top surface of the second type semiconductor layer 123 to the top surface 1212 of the first type semiconductor layer 121, and is defined by a side wall that extends inclinedly.

The second recess 16 extends from the top surface 1212 of the first type semiconductor layer 121 toward the upper surface 101 of the substrate 10, and has a recess bottom 161 adjacent to but not terminated at the upper surface 101. That is, the second recess 16 is formed in the first type semiconductor layer 121. In some embodiments, the second recess 16 extends a predetermined depth from the top surface 1212 of the first type semiconductor layer 121. In some embodiments, the second recess 16 extends a predetermined depth from the top surface 1212 of the first type semiconductor layer 121, and does not penetrate through the first type semiconductor layer 121. In certain embodiments, the second recess 16 extends to the upper surface 101 of the substrate 10 from the top surface 1212 of the first type semiconductor layer 121, i.e., the second recess 16 penetrates through the first type semiconductor layer 121. It should be noted that, in the top view of the light-emitting device as shown in FIG. 1, the second recess 16 has a projected area on the upper surface 101 of the substrate 10 which is within that of the first recess 14.

The inner surface 1211 extends inclinedly along a line to form an inclined angle (α) relative to the upper surface 101 of the substrate 10, and has an inclined length (L). In this embodiment, the inclined angle (α) is not greater than 60° and the inclined length (L) ranges from 0.3 μm to 15 μm, but is not limited thereto. In certain embodiments, the inclined angle (α) ranges from 20° to 45°. Furthermore, in the sectional view of the first type semiconductor layer 121, the inclinedly extending line of the inner surface 1211 is a straight line, but is not limited thereto. In other embodiments, the inclinedly extending line of the inner surface 1211 may has a stepped profile, so that the contact area between the first electrode 21 and the inner surface 1211 can be further increased, thus the current can flow into the first type semiconductor layer 121 in a transverse direction with a relatively high efficiency. In this embodiment, the inclined length (L) is referred as a linear length which starts from a peripheral edge of the inner surface 1211 that is connected to the upper surface 101 of the substrate 10 to an another peripheral edge of the inner surface 1211 that is connected to the top surface 1212 of the first type semiconductor layer 121; and the inclined angle (α) is referred as an angle that is defined as a line that starts from the peripheral edge of the inner surface 1211 to the another peripheral edge of the inner surface 1211 relative to the upper surface 101 of the substrate 10. The inclined length (L) is referred to as an extended length starting from an endpoint of the inclinedly extending line adjacent to the upper surface 101 of the substrate 10 and ending with an endpoint of the inclinedly extending line adjacent to the top surface 1212 of the first type semiconductor layer 121. As mentioned above, the inclined angle (α) is an included angle between the inclinedly extending line and the upper surface 101 of the substrate 10.

The first electrode 21 is disposed in the second recess 16, at least partially covers the inner surface 1211 of the first type semiconductor layer 121, and is electrically connected to the first type semiconductor layer 121. In this embodiment, the first electrode 21 further covers a part of the top surface 1211 of the first type semiconductor layer 121 and the recess bottom 161 of the second recess 16 (i.e., the first electrode 21 completely covers the inner surface 1211 of the first type semiconductor layer 121), and forms an ohmic contact with the first type semiconductor layer 121. Since the first electrode 21 covers the inner surface 1211 of the first type semiconductor layer 121, a current may flow into the first type semiconductor layer 121 from a contact part therebetween when the light-emitting device 1 is driven, i.e., the current may flow into the first type semiconductor layer 121 in a transverse direction, thereby reducing the operating voltage of the light-emitting device 1.

It should be noted that, in a conventional light-emitting diode, the light would be reflected reciprocally between the active layer 122 and the substrate 10 because of waveguide effect, so that the light would be absorbed by the semiconductor layers to affect the luminous efficacy of the light-emitting diode. In order to solve such problem, in this embodiment, the first electrode 21 is disposed in the second recess 16, thereby blocking the waveguide effect in the second recess 16. Thus, the first electrode 21 would reflect more of the light that is emitted by the active layer 122 toward the substrate 10, outside the light-emitting device, so as to enhance the light extraction efficiency of the light-emitting device 1.

In addition, in the first type semiconductor layer 121, if the inclined angle (α) is too small, the top surface 1212 of the first type semiconductor layer 121 exposed from the first recess 14 would be reduced correspondingly, which may pose a risk that the first electrode 21 will be peeled or that the positive voltage is raised to an unstable situation.

The second electrode 22 is disposed on the second type semiconductor layer 123 opposite to the active layer 122. Furthermore, the second electrode 22 is electrically connected to the second type semiconductor layer 123, and forms an ohmic contact with the second type semiconductor layer 123. Each of the first electrode 21 and the second electrode 22 is made of a material selected from the group consisting of Cr, Pt, Au, Ni, Ti, Al, and combinations thereof, but is not limited thereto.

In this embodiment, in the top view of the light-emitting device 1 as shown in FIG. 1, the first recess 14 has a projected area on the upper surface 101 ranging from 20% to 70% of that of the epitaxial light-emitting structure 12. Since a relatively large n-type ohmic contact area is required in the light-emitting device 1, the contact area between the first electrode 21 and the first type semiconductor layer 121 should be ensured. Therefore, if the inclined angle (α) is relatively small, the contact area between the first electrode 21 and the first type semiconductor layer 121 will be increased, i.e., lateral current injection area will be increased to decrease a surface resistivity therebetween, so that the current can efficiently flow into the first type semiconductor layer 121 in a transverse direction. In some embodiments, in the top view of the light-emitting device 1, an overlapping area of the projected areas of the first electrode 21 and the first type semiconductor layer 121 ranges from 10% to 50%, preferably, from 20% to 50%, so that the contact area between the first electrode 21 and the first type semiconductor layer 121 is sufficient.

Referring back to FIGS. 1 and 2, in this embodiment, the light-emitting device 1 further includes a metal structure 23, an insulation layer 30, a first pad 31, and a second pad 32.

The metal structure 23 covers the first electrode 21, i.e., almost entirely covers a top surface 213 of the first electrode 21 opposite to the first type semiconductor layer 121 and the substrate 10 so as to protect the first electrode 21 from damage in subsequent processes. In this embodiment, the first electrode 21 has a bottom surface 211 adjacent to the upper surface 101 of the substrate 10, and a top surface 213 opposite to the bottom surface 211 which is formed with a third recess 18 that extends from the top surface 213 of the first electrode 21 toward the upper surface 101 of the substrate 10, i.e., the third recess 18 is formed within the first electrode 21. The metal structure 23 is disposed in the third recess 18. Furthermore, the third recess 18 has a projected area on the upper surface 101 of the substrate 10 which is within that of the second recess 16. That is, in the top view of the light-emitting device 1, the third recess 18 is located within the second recess 16.

The metal structure 23 may be made of a material selected from the group consisting of Cr, Al, Ti, Ni, Rh, Pt, Au, and combinations thereof. In certain embodiments, the metal structure 23 may be formed as a multi-layered structure that has an adhesive layer and a reflection layer in such order on the first electrode 21. The adhesive layer may be made of Cr, Ni, or Ti. The reflection layer is used for reflecting the light emitted by the active layer 122 toward the substrate 10, so as to enhance the light extraction efficiency of the light-emitting device 1.

It should be noted that, in this embodiment, the first recess 14 has a first depth (H1) ranging from 0.2 μm to 1.5 μm; the second recess 16 has a second depth (H2) ranging from 0.5 μm to 8 μm; and the third recess 18 has a third depth (H3) ranging from 0.5 μm to 8 μm, but is not limited thereto.

The insulation layer 30 covers the substrate 10, the epitaxial light-emitting structure 12, the metal structure 23, and the second electrode 22, and is formed with a first opening 301 and a second opening 302. The first opening 301 is formed to expose the metal structure 23, and the second opening 302 is formed to expose the second electrode 22.

Furthermore, the insulation layer 30 has several advantages depending upon its positional relationships with other structures, such as the substrate 10, the epitaxial light-emitting structure 12, the metal structure 23, and the second electrode 22. For instance, by covering a side wall of the epitaxial light-emitting structure 12, electrical contact between the first type semiconductor layer 121 and the second type semiconductor layer 123 that occurs due to leakage of conducting materials can be avoided, and thus, short circuit of the light-emitting device 1 is avoidable. In addition, the insulation layer 30 may be made from a non-conducting material such as an inorganic material or a dielectric material. For instance, the inorganic material includes silicon, and the dielectric material includes aluminum oxide (AlO), silicon nitride (SiNx), silicon oxide (SiOx), titanium oxide (TiOx), or magnesium fluoride (MgFx). In some embodiment, the insulation layer 30 may be made from silicon dioxide, silicon nitride, titanium oxide, tantalum oxide, niobium oxide, barium titanate, or combinations thereof. For example, the insulation layer 30 is formed as a distributed Bragg reflector (DBR) composed of two different material layers that are alternately laminated and that are made of the aforesaid materials.

The first pad 31 and the second pad 32 are disposed on the insulation layer 30, and are respectively electrically connected to the metal structure 23 and the second electrode 22 by extending through the first opening 301 and the second opening 302. The first pad 31 and the second pad 32 are simultaneously formed using the same material, so that the first pad 31 and the second pad 32 may have the same configuration.

In some embodiments, referring to FIG. 1 again, in the top view of the light-emitting device 1, the first electrode 21 includes a connection portion and a plurality of spaced-apart finger electrode portions 212 connected to the connection portion. The epitaxial light-emitting structure 12 includes a plurality of the second recesses 16, which are formed by removing corresponding portions of the light-emitting structure 12. A part of the second recesses 16 is located in the finger electrode portions 212, where the current is prohibited from flowing in the transverse direction so as to have an effective current blocking.

In such case, the second recesses 16 located in the finger electrode portions 212 of the first electrode 21 have a maximum pore size ranging from 1 μm to 35 μm, so as to obtain sufficient light-emitting area of light-emitting device 1 (i.e., an area of the active layer 122), and have a minimum pore size that is not less than 0.5 μm, so as to balance the electrical property of the light-emitting device 1 and the precision accuracy of a processing machine as required. Specifically, since the inner surface 1211 of the first type semiconductor layer 121 extends inclinedly, for each of the second recess 16, a maximum pore size refers to a diameter of its opening at the top surface 1212 of the first type semiconductor layer 121 side, and the minimum pore size refers to a diameter of its recess bottom 161. Furthermore, any two adjacent ones of the second recesses 16 have a center-to-center spacing ranging from 5 μm to 80 μm. Since the second recesses 16 may have different pore sizes and are distributed widely, the center-to-center spacing between the two adjacent ones of the second recesses 16 may be varied. For instance, when the second recesses 16 have the pore size ranging from 0.5 μm to 10 μm, the center-to-center spacing between the two adjacent ones of the second recesses 16 is relatively small, whereas when the second recesses 16 have the pore size ranging 20 μm to 50 μm, the center-to-center spacing between the two adjacent ones of the second recesses 16 is relatively large. In certain embodiments, the center-to-center spacing of the any two adjacent ones of the second recesses 16 located in the finger electrode portions 212 of the first electrode 21 ranges from 5 μm to 30 μm.

In some embodiments, referring to FIG. 1, in the top view of the light-emitting device 1, each of the first electrode 21 is configured to surround the active layer 122 of the epitaxial light-emitting structure 12. The second recess 16 has a projected area on the upper surface 101 of the substrate 10 overlapping with that of the first electrode 21. In particular, in the case of the light-emitting device 1 having a plurality of the first electrodes 21 and the second recesses 16, a part of the second recesses 16 located in a peripheral edge of the light-emitting device 1 has projected areas on the upper surface 101 of the substrate overlapping with those of the corresponding first electrodes 21. To be specific, in the top view of the light-emitting device 1, the second recesses 16 located at the peripheral edge of the light-emitting device 1 extend inwardly, and exceed peripheral edges of the corresponding first electrodes 21, so that the first electrodes 21 that surround the active layer 122 cover the side walls of the corresponding second recesses 16. Thus, the light extraction efficiency of the light-emitting device 1 can be enhanced. Moreover, since the first electrodes 21 are configured to surround the active layer 122, the contact area between the first electrodes 21 and the first type semiconductor layer 121 can be increased, thereby reducing the operating voltage of the light-emitting device 1.

In some embodiments, in the top view of the light-emitting device 1, the second type semiconductor layer 123 is formed to be E-shaped and is formed to surround the part of the second recesses 16 that is located in the finger electrode portions 212. With such configuration, the portion of the first electrodes 21 located in the part of the second recesses 16 will reflect more of the light that is emitted by the active layer 122 toward the substrate 10 and outside the light-emitting device 1, so as to enhance the light extraction efficiency of the light-emitting device 1.

In some embodiments, the light-emitting device 1 is formed as a flip-chip light-emitting diode. In such case, the inclined angle (α) may be reduced, so that the contact area between the first electrode 21 and the first type semiconductor layer 121 can be further increased. In certain embodiments, in the top view of the light-emitting device 1, the first electrode 21 has a projected area on the upper surface 101 of the substrate 10 which ranges from 3% to 40% of that of the epitaxial light-emitting structure 12.

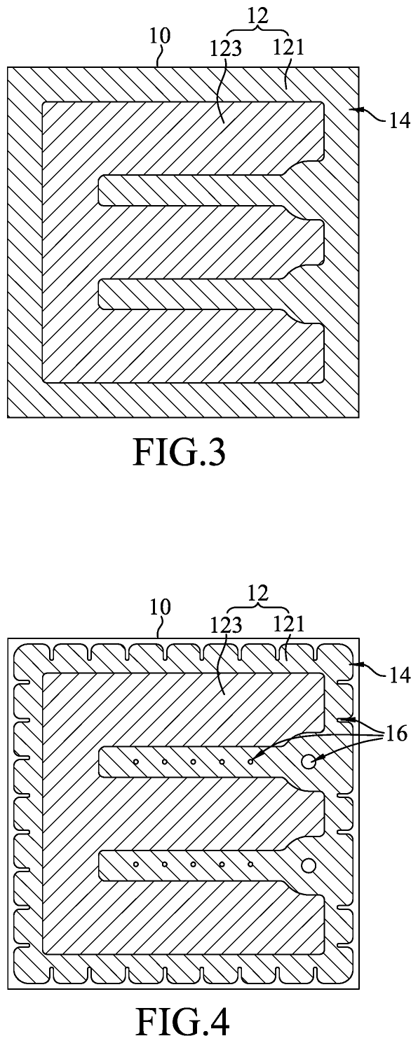

FIGS. 3 to 8 illustrate consecutive steps of a method for manufacturing the first embodiment of the light-emitting device 1 shown in FIGS. 1 and 2. It should be noted that, in the FIGS. 3 to 8, the shaded region of each figure refers to additional structures relative to FIGS. 1 and 2.

In step 1, referring to FIG. 3, the substrate 10 having the upper surface 101 is provided. The epitaxial light-emitting structure 12 is formed on the upper surface 101 of the substrate 10 by forming the first type semiconductor layer 121, the active layer 122, and the second type semiconductor layer 123 on the upper surface 101 in such order. Then, the epitaxial light-emitting structure 12 is etched from the second type semiconductor layer 123 toward the first type semiconductor layer 121 to expose the first type semiconductor layer 121, so as to form the first recess 14. As shown in FIG. 3, the first recess 14 is represented as a region marked with diagonal lines extending from top left to bottom right, and the epitaxial light-emitting structure 12 is represented as the total region of a region marked with diagonal lines extending from top right to bottom left and the region marked with diagonal lines extending from top left to bottom right.

In step 2, referring to FIG. 4, the first type semiconductor layer 121 is etched to expose a part of the substrate 10, i.e., a peripheral edge and an inner section of the first type semiconductor layer 121 are removed to form the second recesses 16.

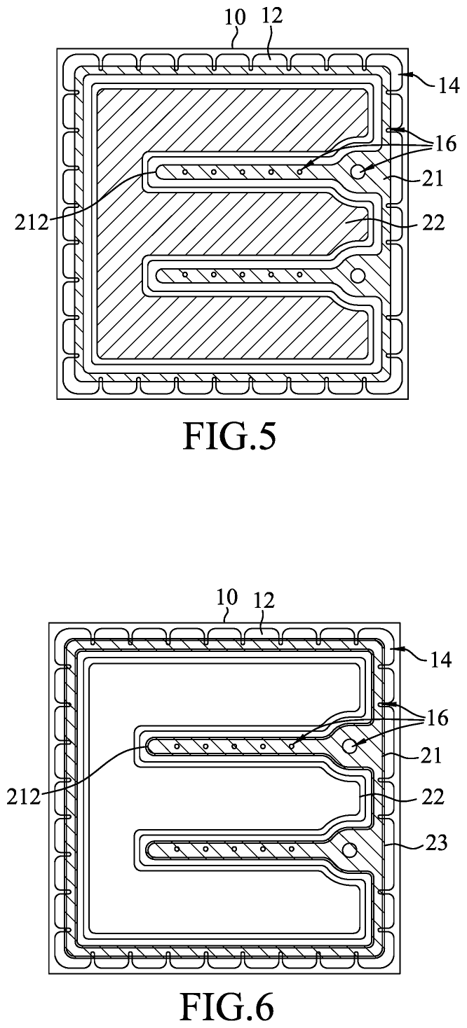

In step 3, referring to FIG. 5, the first electrodes 21 are formed on the first type semiconductor layer 121 and in the second recesses 16, and the second electrodes 22 are formed on the second type semiconductor layer 123. In this embodiment, the top surface 1212 of the first type semiconductor layer 121 is partially covered by the first electrode 21, and the inner surface 1211 of the first type semiconductor layer 121 is completely covered by the first electrodes 21.

It should be noted that, by virtue of the first electrodes 21 formed to cover the inner surface 1211 of the first type semiconductor layer 121, when the light-emitting device 1 is driven, the current would flow into the first type semiconductor layer 121 from the contact part of the inner surface 1211 and the first electrodes 21. That is, with such configuration, the current can flow into the first type semiconductor layer 121 in a transverse direction, thereby reducing the operating voltage of the light-emitting device 1.

In step 4, referring to FIG. 6, the metal structure 23 is formed to cover the first electrodes 21. The metal structure 23 is used to reflect the light that is emitted by the active layer 122 toward the substrate 10, so as to enhance the light extraction efficiency of the light-emitting device 1. As mentioned above, the metal structure 23 is useful for protecting the first electrodes 21 from damage caused by subsequent processes.

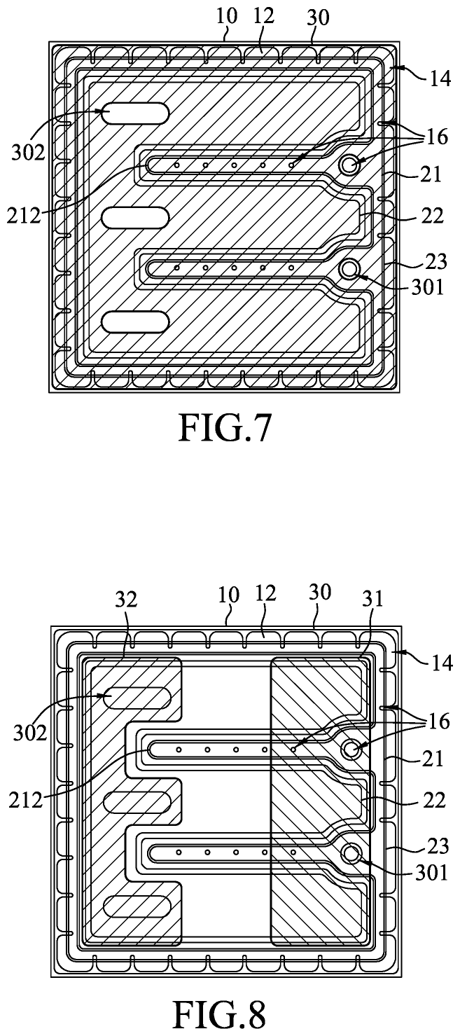

In step 5, referring to FIG. 7, the insulation layer 30 is formed to cover the substrate 10, the epitaxial light-emitting structure 12, the metal structure 23, and the second electrodes 22. A plurality of the first opening 301 and a plurality of the second openings 302 are formed in the insulation layer 30 to expose the metal structure 23 and the second electrodes 22, i.e., the first openings 301 are formed to expose the metal structure 23, and the second openings 302 are formed to expose the second electrodes 22. The insulation layer 30 is used to avoid short circuit of the light-emitting device 1, and to protect the epitaxial light-emitting structure 12, the first and second electrode 21, 22, and the metal structure 23 that are formed in the aforesaid steps.

In step 6, referring to FIG. 8, a plurality of the first pads 31 and a plurality of the second pads 32 are formed on the insulation layer 30. The first pads 31 are electrically connected to the metal structure 23 through the first openings 301 of the insulation layer 30, and the second pads 32 are correspondingly and electrically connected to the second electrodes 22 through the second openings 302 of the insulation layer 30, thereby obtaining the light-emitting device 1 as shown in FIGS. 1 and 2.

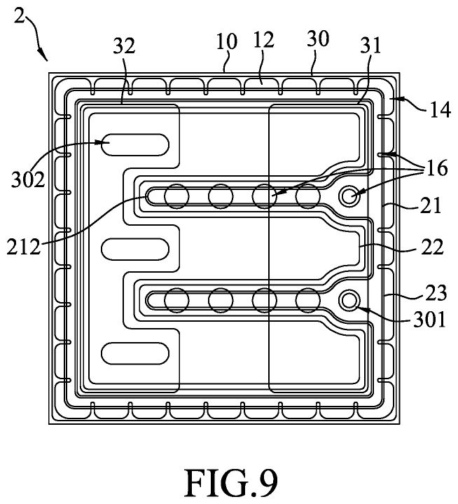

FIG. 9 is a top view illustrating a second embodiment of a light-emitting device 2 according to the disclosure. The light-emitting device 2 is generally similar to aforementioned light-emitting device 1 shown in FIG. 1, except for the following differences.

In this embodiment, referring to FIG. 9, each of the second recesses 16 is formed to exceed the finger electrode portions 212 of the first electrode 21, so as to reduce the inclined angle (α). Thus, current flow efficiency of the first type semiconductor layer 121 in a transverse direction and the light reflection performance can be enhanced. Furthermore, the second recesses 16 located at the peripheral edge of the light-emitting device 2 are extended inwardly, and exceed the peripheral edges of the first electrodes 21 that surround the active layer 122. That is to say, in this embodiment, the design of the second recess 16 exceeding the first electrode 21 not only applies to the second recesses 16 located at the finger electrode portions 212 but also the recesses 16 located at the peripheral edges of the first electrodes 21.

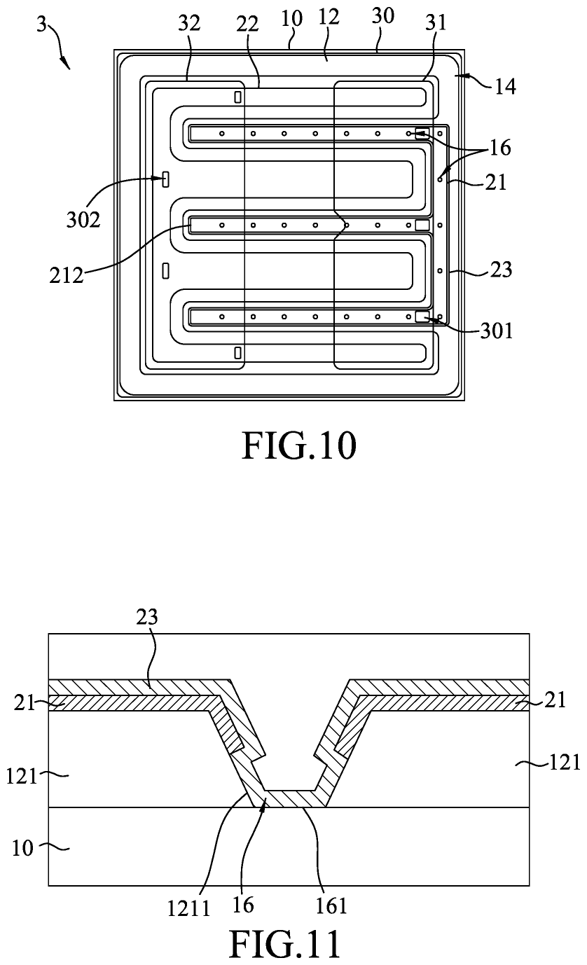

FIG. 10 is a top view illustrating a third embodiment of a light-emitting device 3 according to the disclosure. The light-emitting device 3 is generally similar to aforementioned light-emitting device 1 shown in FIG. 1, except for the following differences.

In this embodiment, active layer 122 of the epitaxial light-emitting structure 12 is not surrounded by the first electrode. With such configuration, since areas of the first electrodes 21 are reduced, the phenomenon of the light emitted by the light-emitting device 3 being blocked by the first electrodes 21 can be alleviated. Thus, the light extraction efficiency of the light-emitting device 3 may be further enhanced. Furthermore, since the operating voltage of the light-emitting device 3 is increased because of decrease in the area of the first electrodes 21, the numbers or the width of the finger electrode portions 212 of the first electrodes 21 can be increased to avoid such problem.

FIGS. 11 to 13 are enlarged sectional view illustrating variations in a configuration of the second recess 16 of the light-emitting device 1 of the disclosure. Referring to FIGS. 11 to 13, in each of the variations in the configuration of the second recess 16, the inner surface 1211 of the first type semiconductor layer 121 has an uncovered portion exposed from the first electrodes 21.

Referring to FIG. 11, the metal structure 23 covers the uncovered portion of the inner surface 1211 and the recess bottom 161 of the second recess 16. By virtue of the metal structure 23 covering the inner surface 1211, the light reflective efficiency would be further enhanced, thus the light-emitting device 1 having a superior light extraction efficiency may be obtained.

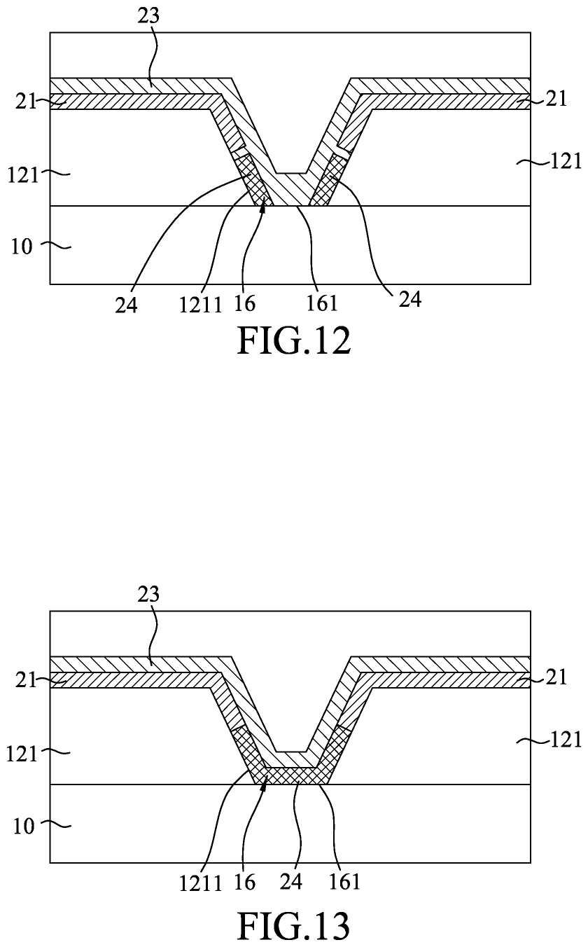

Referring to FIG. 12, the light-emitting device 1 further includes a reflection-enhancing layer 24. The reflection-enhancing layer 24 partially covers the uncovered portion of the inner surface 1211 and the recess bottom 161 of the second recess 16. The metal structure 23 covers the reflection-enhancing layer 24, the first electrode 21, and the remaining inner surface 1211. The reflection-enhancing layer 24 may be made of a metal material having a high reflectivity such as aluminum, silver, etc. In some embodiments, the reflection-enhancing layer 24 is formed as a non-metal structure such as a distributed Bragg reflector. With such configuration, in comparison with the configuration shown in FIG. 11, the light reflective efficiency will be further enhanced.

Referring to FIG. 13, the reflection-enhancing layer 24 completely covers the uncovered portion of the inner surface 1211 and the recess bottom 161 of the second recess 16. With such configuration, in comparison with the configurations shown in FIGS. 11 and 12, respectively, the light reflective efficiency will be further enhanced.

It should be noted that, in some embodiments, the first electrodes 21 are only disposed on the top surface 1212 of the first type semiconductor layer 121, and do not cover the inner surface 1211 of the first type semiconductor layer 121. The metal structure 23 fills the second recess 16 and covers the inner surface 1211. With such configuration, the current may also flow into the first type semiconductor layer 121 from a contact part between the metal structure 23 and the inner surface 1211. Furthermore, a good light reflective efficiency may also be obtained.

The present disclosure also provides an embodiment of a light-emitting apparatus which includes at least one of the aforesaid light-emitting device 1, 2, 3 as shown in FIGS. 1, 9, 10, respectively.

In sum, by virtue of the first electrode 21 formed to cover the inner surface 1211 of the first type semiconductor layer 121, the current can flow into the first type semiconductor layer 121 in a transverse direction, thus the operating voltage of the light-emitting device 1 can be reduced. Moreover, by virtue of the first electrodes 21 disposed in the second recesses 16, the first electrodes 21 will reflect more of the light that is emitted by the active layer 122 toward the substrate 10, thereby enhancing the light extraction efficiency of the light-emitting device 1.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A light-emitting device, comprising:
a substrate having an upper surface;
an epitaxial light-emitting structure disposed on said upper surface, said epitaxial light-emitting structure including
a first type semiconductor layer, an active layer, and a second type semiconductor layer formed on said upper surface in such order,
a first recess extending from said second type semiconductor layer to said first type semiconductor layer through said active layer, and
a second recess extending from said first type semiconductor layer toward said upper surface, said first type semiconductor layer having an inner surface defining said second recess;
a first electrode disposed in said second recess, at least partially covering said inner surface of said first type semiconductor layer, and being electrically connected to said first type semiconductor layer; and
a second electrode disposed on said second type semiconductor layer, and being electrically connected to said second type semiconductor layer,
wherein said first type semiconductor layer includes an aluminum component, in a top view of said light-emitting device, said first recess having a projected area on said upper surface ranging from 20% to 70% of that of said epitaxial light-emitting structure.

2. The light-emitting device as claimed in claim 1, wherein said inner surface of said first type semiconductor layer extends inclinedly along a line, the line forming an inclined angle of not greater than 60° relative to said upper surface of said substrate.

3. The light-emitting device as claimed in claim 1, wherein said inner surface of said first type semiconductor layer extends inclinedly and has an inclined length ranging from 0.3 μm to 15 μm.

4. The light-emitting device as claimed in claim 1, wherein said first type semiconductor layer further includes a top surface connected to said inner surface and away from said upper surface, said second recess having a recess bottom adjacent to said upper surface, said first electrode further covering said top surface of said first type semiconductor layer and said recess bottom of said second recess.

5. The light-emitting device as claimed in claim 1, further comprising a metal structure covering said first electrode.

6. The light-emitting device as claimed in claim 5, wherein said metal structure is made of a material selected from the group consisting of Cr, Al, Ti, Ni, Rh, Pt, Au, and combinations thereof.

7. The light-emitting device as claimed in claim 5, wherein said first electrode has a bottom surface adjacent to said upper surface of said substrate and a top surface opposite to said bottom surface and is formed with a third recess extending from said top surface of said first electrode toward said upper surface of said substrate, said metal structure being disposed in said third recess.

8. The light-emitting device as claimed in claim 7, wherein said third recess has a projected area on said upper surface of said substrate being within that of said second recess.

9. The light-emitting device as claimed in claim 7, wherein said first recess has a first depth ranging from 0.2 μm to 1.5 μm, said second recess having a second depth ranging from 0.5 μm to 8 μm, said third recess having a third depth ranging from 0.5 μm to 8 μm.

10. The light-emitting device as claimed in claim 5, wherein said inner surface of said first type semiconductor layer has an uncovered portion exposed from said first electrode, said second recess having a recess bottom adjacent to said upper surface, said metal structure covering said uncovered portion of said inner surface and said recess bottom of said second recess.

11. The light-emitting device as claimed in claim 5, wherein said inner surface of said first type semiconductor layer has an uncovered portion exposed from said first electrode, said second recess having a recess bottom adjacent to said upper surface, said light-emitting device further comprising a reflection-enhancing layer partially covering said uncovered portion of said inner surface and said recess bottom of said second recess, said metal structure covering said reflection-enhancing layer.

12. The light-emitting device as claimed in claim 11, wherein said reflection-enhancing layer completely covers said uncovered portion of said inner surface and said recess bottom of said second recess.

13. The light-emitting device as claimed in claim 1, wherein said first electrode includes a connection portion and a plurality of finger electrode portions connected to said connection portion, said epitaxial light-emitting structure including a plurality of said second recesses, a part of said second recesses being located in said finger electrode portions.

14. The light-emitting device as claimed in claim 13, wherein said second recesses located in said finger electrode portions have a maximum pore diameter ranging from 1 μm to 35 μm, and a minimum pore diameter of not less than 0.5 μm.

15. The light-emitting device as claimed in claim 13, wherein, in the top view of said light-emitting device, said first electrode is configured to surround said active layer of said epitaxial light-emitting structure, said second recess having a projected area on said upper surface of said substrate overlapping with that of said first electrode.

16. The light-emitting device as claimed in claim 1, wherein any two adjacent ones of said second recesses have a center-to-center spacing ranging from 5 μm to 80 μm.

17. The light-emitting device as claimed in claim 1, wherein said active layer of said epitaxial light-emitting structure is configured to emit light having a wavelength ranging from 200 nm than 420 nm.

18. The light-emitting device as claimed in claim 1, wherein, said light-emitting device is configured as a flip-chip light-emitting device, in the top view of said light-emitting device, said first electrode having a projected area on said upper surface of said substrate which ranges from 3% to 40% of that of said epitaxial light-emitting structure.

19. The light-emitting device as claimed in claim 1, wherein said epitaxial structure includes a plurality of said second recesses, in the top view of said light-emitting device, a part of said second recesses being surrounded by said second type semiconductor layer.

20. A light-emitting apparatus comprising: at least one light-emitting device as claimed in claim 1.
